(19) United States
(12) Patent Application Publication
(10) Pub. No.: US 2010/0326699 A1
(43) Pub. Date: Dec. 30, 2010

(54) Polymeric High Voltage Insulator with a Hard, Hydrophobic Surface

(76) Inventor: Corinne Jean Greyling, Cape Town (ZA)

Correspondence Address: COOLEY LLP;ATTN: Patent Group, Suite 1100, 777 - 6th Street, NW, WASHINGTON, DC, 20001, US

(21) Appl. No.: 12/746,516

(22) PCT Filed: Dec. 3, 2008
(86) PCT No.: PCT/ZA08/00121

§ 371 Date: Sep. 2, 2010

(30) Foreign Application Priority Data
Dec. 5, 2007 (ZA) 2007/10602

(51) Int. Cl. H01B 3/00; C08L 83/04; B32B 3/10; C08K 3/22; C08K 3/40; C23C 14/28; B05D 1/18

(52) U.S. Cl. 174/137 B; 524/588; 428/143; 524/430; 524/432; 524/494; 427/596; 427/430.1; 977/773

(57) ABSTRACT

The present invention relates to phase separated siloxane-hydrocarbon copolymer surfaces which are hard and hydrophobic and can be superhydrophobic by the addition of nanoparticles. More specifically the siloxane oligomer/polymer precursor is terminated with (a) chemically reactive group(s). The bond between the siloxane moiety and the hydrocarbon functional moiety is a Si atom directly bonded to a carbon atom. It is applied (for example) to the entire surface of a fibre reinforced and void-free polymer concrete core with 60 to 88% polymeric and inorganic fillers for application as a high voltage insulator. The product has high mechanical strength, impact resistance and good electrical insulation properties. The coating provides good UV resistance, hydrophobicity and a hard self-cleaning surface for use as outdoor high voltage electrical insulator in areas of high pollution with low leakage currents when energised and can also be applied to other products.

### TECHNICAL FIELD

THIS INVENTION relates to polymeric high voltage insulators. It relates, in particular, to siloxane hydrocarbon with coating compositions with nanoparticles, to methods of making coating compositions and to high voltage insulation objects coated with the coating compositions. It also relates to a fibre reinforced and flyash filled polymeric concrete inner core and a method for making the concrete core.

### BACKGROUND ART

Materials which exhibit good hydrophobic properties, such as silicone rubber (polydimethylsiloxane, PDMS or SR or SIR) and Teflon®, (polytetrafluoroethylene, PTFE), are soft materials and these materials typically pick up more dirt and dust than hard materials. Further, when used outdoors and specifically in areas of high marine or industrial pollution, the dust will contain conductive salts and corrosive chemicals.

In the case of insulators used in the distribution and transmission of electricity, in times of high humidity, condensation or rain the conductive pollutants will form a conductive layer on the surface of the insulator. This leads to high surface leakage currents, power losses on electrical distribution and transmission power grids and surface heating which often results in failure of the electrical apparatus by flashover and rapid material degradation giving a reduced service-life.

Many present insulator designs are also susceptible to mechanical damage during transportation and installation and require special packaging and handling requirements.

There is accordingly a general trend worldwide to replace heavy, brittle, hydrophilic glass and porcelain as the material of choice for high voltage electric insulators with insulators made from lighter weight, impact resistant and surface scratch resistant polymeric materials. These insulators are referred to as non-ceramic insulators (NCI) as defined by the International Electrotechnical Commission, IEC.

The history of polymeric insulators began in the 1940s when organic insulating materials were used to manufacture high voltage indoor electrical insulators from Bisphenol-A based epoxy resins. NCI materials are more lightweight, impact resistant, vandal resistant and could be used to form larger more complex parts than glass and porcelain. Polymeric insulators for outdoor use were made feasible by the discovery in the 1950s that aluminium trihydrate or ATH filler (Al(OH)₃) increases the tracking and erosion resistance of the polymeric materials. The ATH provides anti flammability, (flame retardant), properties by releasing bound water of hydration during heating to form aluminium oxide Al₂O₃, in a reversible reaction.

However, polymeric insulators for outdoor application on transmission lines were not developed until the late 1960s. In the late 1960s and early 1970s, manufacturers introduced the first generation of commercial polymeric transmission line suspension long-rod insulators with a pultruded glass fibre core i.e. highly aligned boron-free E-grade glass filaments in an epoxy or polyester matrix, and crimped metal end fittings.

Originally, composite long-rod non-ceramic insulators contained ethylene propylene rubbers and ethylene propylene diene (EPR and EPDM). Rosenthal Company of Germany (later Hoescht and now Lapp Insulators) (1976), and Reliable Company of the U.S.A, (1983), introduced silicone rubber (SIR). Room-temperature cured silicone rubber (RTV) composite insulators were used in Germany in 1977 for up to 123 kV and in 1979 for up to 245 kV. High temperature cured silicone rubber (HTV) insulators were installed for the first time on a 400 kV line near Cape Town, South Africa in 1987. In the late 1990's a liquid silicone rubber (LSR) based insulator was introduced. Presently the global market division between the EPR hydrocarbon based insulators to the silicone rubber based insulators is 10:90.

Line post insulators typically used on distribution voltages (<150 kV) are used in compression mode, where the conductor is mechanically supported by the insulator which is attached via a bolt and a screw in the insulator metal insert to the cross-arm or the side of a utility pole. Epoxy resins have been used in this application for more than 30 years with mixed performance results. Typically aromatic bisphenol-A based epoxies have been used only indoors and cycloaliphatic epoxy formulations with superior UV resistance have been used in outdoor applications. The bisphenol-A epoxy insulators have shown material erosion and filler exposure producing a roughened surface and giving rise to increased leakage currents after a few years indoor exposure while energised. The cycloaliphatic epoxy insulators have shown material erosion and filler exposure producing a roughened surface (roughness on the micron scale with pits typically 100 microns and larger) giving rise to a deterioration of the degree of hydrophobicity and increased leakage currents after a few years exposure while energised outdoors.

Polymer concrete insulators have been used extensively in the USA (EPRI Patent/Gunasekaran/Polysil®) and also South America and in Eastern Europe, (Poland). The commercial products are used uncoated and the binder is typically epoxy resin. The field performance of these insulators has however been variable, and is usually classified for use in Class 1, mild pollution conditions.

A drawback of the current technology is that when silicone rubber, EPR, alloys, (EPR or EPDM with added silicone oils) and cycloaliphatic materials are used on outdoor electrical insulators they build up leakage currents over time which accelerate breakdown of the polymeric insulator shed material and cause power losses and possible flashover and power failures/outages.

It has been shown that the rate of build up of leakage currents on the insulator surface is suppressed on a hydrophobic surface. To this end, silicone oil has been blended with EPR and called an alloy, (ELBROC® Ohio Brass, USA) or with ethylene-vinyl-acetate, EVA, (Tyco Electronics, previously Raychem Corp., UK). Field-testing at the Koeberg Insulator Pollution Test Site, KIPTS, in South Africa has shown that these materials loose their hydrophobic properties within a year of being energised outdoors. The failure has been determined to be a result of the loss of the low molecular weight, (LMW), silicone oil migrating from the bulk to the surface and then being lost by evaporation and oxidation leaving the exposed hydrocarbon rubber susceptible to UV degradation, from natural background source and corona induced discharge sources.

Recently Vantico, (Basel, Switzerland, previously Ciba Geigy and Huntsman Corporation) developed a hydrophobic cycloaliphatic epoxy, specifically for use in HV NCI, by incorporating fluorinated silanes (molecule with a single Si atom) in the composition. These products have also not performed well at the KIPTS test site, in South Africa.

The relatively superior performance of silicone rubber based formulations for the insulator sheds and RTV coatings on porcelain insulator cores is ascribed to the hydrophobicity (low surface tension of 22 dynes·cm⁻¹) when new and the ability for hydrophobicity recovery. The mechanism for the loss of hydrophobicity has been reported to be due to oxidation processes and/or the “flipping” of the labile methyl groups away from the surface with the exposure of the partially ionic Si—O backbone.

On polluted insulators, it is known that the low molecular weight (LMW), linear and cyclic silicone additives and degradation by-products migrate through the silicone material bulk and then the pollution layer and recoat the pollutants to a varying degree for different silicone rubber formulations thereby allowing a recovery of the degree of hydrophobicity. These LMW siloxanes have a low boiling point and are readily lost again reducing the hydrophobicity of the surfaces and again increasing the surface energy.

In the late 1980's James McGrath and Iskender Yilgor at Virginia Polytechnic in the USA developed a range of siloxane-hydrocarbon oligomers and block copolymers. It was found that a small addition of a siloxane-epoxy copolymer, less than 1 weight percent blended into a base epoxy resin was able to reduce the surface tension from 42 to 22 dynes·cm⁻¹. In addition these oligomers can be formulated to have hydrolytically stable Si—C linkages.

It is an object of the invention to address at least some of the problems described above.

### DISCLOSURE OF INVENTION

According to the invention a high voltage electrical insulator used indoors or outdoors up to 1000 kV in AC and DC applications includes a coating, where the surface contains a siloxane hydrocarbon copolymer made from an organofunctional siloxane oligomer or polymer and a hydrocarbon based oligomer or polymer and micron and nano sized fillers and other additives.

Preferably within the organofunctional siloxane structure the Si atom is directly covalently bonded to the carbon atom of the hydrocarbon moiety of the functional group.

Further once the coating is cured, the siloxane hydrocarbon is phase separated such that the surface is enriched in siloxane relative to the bulk and that the siloxane is covalently bonded into the hydrocarbon bulk.

The nanosized filler particles may be enriched in the free surface region relative to the bulk of the coating and provide ordered micron and nanoscaled roughness to the free surface to create a superhydrophobic surface and photocatalytic degradation of organic substances such as moss, algae and hydrocarbon pollutants.

The coating may contain an organofunctional polydimethylsiloxane selected from oligomers or polymers of the formula (A′) or (A″).

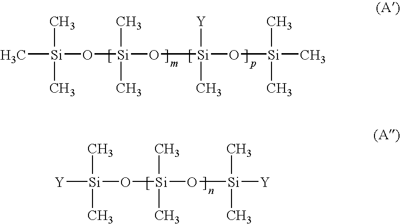

and having between about 5 and about 2000 siloxane groups, in which Y is a reactive substituent.

(A′) and (A″) may have any of the following formula:

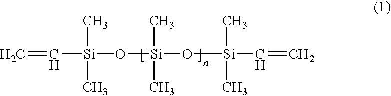

vinyl terminated polydimethylsiloxanes, CAS: [68083-19-2]; n=5 to 480;

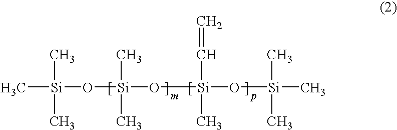

vinylmethylsiloxane-dimethylsiloxane copolymers, trimethylsiloxy terminated, CAS: [67762-94-1]; m=10 to 100; p=1 to 5

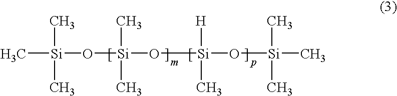

methylhydrosiloxane-dimethylsiloxane copolymers, trimethylsiloxy terminated, CAS: [68037-59-2];

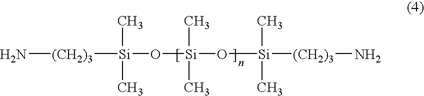

α,ψ-Aminopropyl terminated polydimethylsiloxane, CAS: [106214-84-0]; n=10 to 2 000

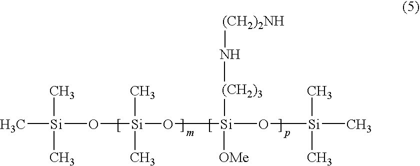

α,ψ-Aminopropyl terminated polydimethylsiloxane, CAS: [106214-84-0]; n=10 to 2 000

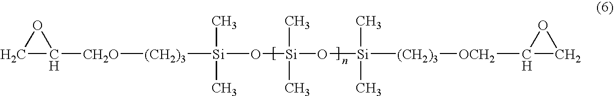

epoxypropoxypropyl terminated polydimethylsiloxanes, CAS: [102782-97-8];

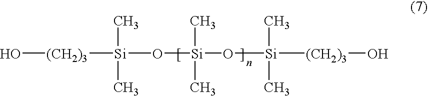

carbinol (hydroxyl) terminated polydimethylsiloxanes, CAS: [156327-07-0];

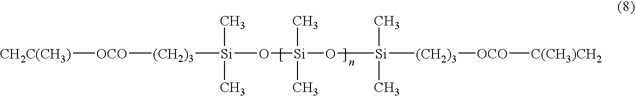

methacryloxypropyl terminated polydimethylsiloxanes, CAS: [58130-03-3];

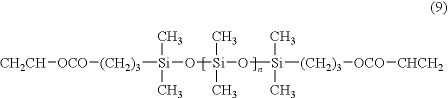

(3-Acryloxy-2-hydroxypropyl) terminated polydimethylsiloxanes, CAS: [128754-61-0].

The organofunctional polydimethylsiloxane (A′) or (A″) may have from 2 to about 2000 repeat siloxane {—Si(CH₃)₂—O—} units, and an associated molecular weight of from about 116 to about 35 000 g·mol⁻¹ and preferably from about 900 to about 11 000 g·mol⁻¹.

The reactive substituent Y may be a monofunctional or a difunctional group and may be selected from vinyl substituents, hydrogen, alkoxy substituents, aminoalkyl substituents, alkyldiamino substituents, methoxy substituents, epoxy substituents, epoxy-alkoxy substituents, alkyl ester, mercapto substituents and the like.

Preferably the reactive substituent Y will have a reactive end group which is separated from the polydimethylsiloxane polymer or oligomer by about 2 to 10 methylene groups and preferably by about 3 methylene groups. Where the polymer or oligomer is (A″), the reactive substituents Y will be the same.

The invention is also directed to a method of preparing an insulator coating which includes the following steps; firstly grafting organofunctional siloxanes (A′) or (A″) onto micron and or nanosized metal oxide filler particles (MO), preparing a resin (C), adding the grafted fillers to the resin to form (A)ₓ(MO)(A)ₓ or (A″)ₓ(MO) and thereafter adding other fillers and additives.

The grafting reaction of bonding the organofunctional siloxane to the filler particle may be performed in a dilute solution of the dispersed filler in a solvent whilst stirring.

The filler may for example be anatase or rutile titanium dioxide, silicon oxide, aluminium oxide or zinc oxide nanoparticles, or a mixture of various metal oxide nanoparticles, in particle size about 2 to 100 nm and preferably 4 to 10 nm.

80 nm titanium dioxide nanoparticles may be dispersed in toluene at a concentration of 10 g per 10 ml toluene before the organofunctional siloxane fluid (or a mixture of organofunctional siloxanes of various molecular weight and functional groups) is added.

Titanium dioxide nanoparticles may be dispersed in toluene and sonicated before the organofunctional siloxane fluid is added drop wise whilst stirring.

A method of preparing an insulator coating as previously described includes the following steps; preparing a base resin (C), then adding organofunctional siloxanes and thereafter fillers and other additives to the formulation.

A method of preparing an insulator coating as previously described includes the following 5 alternative steps of preparing the resin component (D).

In the first route, (A′) or (A″) are separately copolymerised with the functional oligomers or monomers (B) using a free-radical, thermal or UV curing system to produce copolymers of the type (A′)(B)(A′) or (A″)(B). Then, in a separate process, the copolymers (A′)(B)(A′) or (A″)(B) are blended with the base resin (C) to form a resin component (D1) as an interpenetrating network in a solvent.

In the second route, (A′) or (A″) are again separately copolymerised with the functional oligomers or monomers (B) using a free-radical, thermal or UV curing system to produce copolymers of the type (A′)(B)(A′) or (A″)(B) as before. Then, in a separate process, the copolymers (A′)(B)(A′) or (A″)(B) are reacted with the base resin (C) to form a copolymer by a free-radical, thermal, IR or UV curing system in a common solvent to form a resin component (D2).

In the third route, (A′) or (A″) are directly blended with (C) in a solvent. The resulting low viscosity resin composition (D3) is then cured only once the other components of the final coating formulation, as described further below have been added.

In the fourth route (A′) or (A″) are polymerized directly with (C) in a free-radical, thermal or UV activated cure system as before to form a resin component (D4).

A method of preparing an insulator coating as previously described where the mass ratio of the polydimethylsiloxane (A′) or (A″) and the total hydrocarbon polymer, oligomer and monomer (B plus C in the first and second routes and only C in the third and fourth routes described in claim 16) may be between about 0.5:100 and 50;100 and is preferably between about 150:100 and 35:100.

The invention also includes a method of preparing an insulator coating as described where the functionalised polymers, oligomers or monomers (B) may be selected from polymethylmethacrylates, polymethacrylates, polyacrylates, cycloaliphatic or other epoxy compounds, polyamides, polyesters, (PET or PBT including cyclic butylterepthalate), vinyl esters, polyimides, polyphenylene-sulphide, polysiloxanes, polyolefins and polyurethanes or any copolymer of these.

Further in a method of preparing an insulator coating the base resin (C) which could be in a solvent or molten form may be selected from polymethylmethacrylates, polymethacrylates, polyacrylates, polyamides, cycloaliphatic or other epoxy compounds, polyamides, polyesters, (PET or PBT including cyclic butylterepthalate and siliconised polyester), vinyl esters, polyimides, polyphenylene-sulphide, polysiloxanes, polyolefins and polyurethanes or any copolymer of these.

Further in a method of preparing a coating the polymerisation step may be initiated by ultraviolet radiation, infrared radiation, the addition of a free radical initiator such as a peroxide or thermally.

Further a method of preparing a coating may include incorporating one or more additional components in the process steps of the invention.

A method of preparing a coating includes for example, fillers in the form of particles of TiO₂, SiO₂, ZrO₂, ZnO₂ or Al₂O₃/ATH nanoparticles (d_{0.5}<600 nm) or nanostructured nanoparticles (d_{0.5}<900 nm), and preferably less than 100 nm, with low impurities may be incorporated in the coating composition at a loading of about 0 to 150 weight percent of the resin composition and preferably between 3 and 15 weight percent. The fillers may be pre-treated with silanes or titinates or be untreated and of high purity (>99%).

A method of preparing a coating further includes for example, fillers in the form of particles of TiO₂, SiO₂, ZrO₂, ZnO₂ or Al₂O₃/ATH micron sized particles (d_{0.5}<25 μm) and preferably less than 50 μm may be incorporated in the coating composition at a loading of about 0 to 150 weight percent of the resin composition and preferably between 70 and 120 weight percent. The fillers may be pre-treated with silanes or titinates or be untreated and of high purity (>99%).

In a method of preparing a coating the fillers may be incorporated as discrete particles and or applied to the surface of the coated product for example using laser vapour deposition or be formed in situ by a sol-gel technique or by incorporation in the coating formulation or by dip-coating in a separate processing step from a solution of titanium, zirconium, aluminium or silicon precursors. The TiO₂ preferably has an anatase and not a rutile crystal structure.

Further a method of preparing a coating may include one or more organic dyes or inorganic pigments as additives in the coating composition at a level of between about 0 and 6 ppm of the composition.

The additives may include incorporating low molecular weight (LMW) siloxanes in the coating composition at a concentration of between about 0 and 5 weight percent of the composition to aid in the processing of the coating formulation and to improve the hydrophobic properties of the surface.

Further the additives may include incorporating solid glass spheres (micron to nanometer diameter, 1000 micron to 100 nm) at between about 0 and 15 weight percent of the coating composition to change the surface hardness.

Further the additives may include one or more flame-retardants such as aluminium tri-hydrate. The aluminium tri-hydrate preferably has a particle size less than 100 micrometers and a loading of between about 0 and 40 weight percent of the composition.

Further the additives may include incorporating one or more UV stabilisers which absorb UVA, UVB and UVC (400 nm to 250 nm) at an amount of between about 0 and 4 weight percent and preferably 1 to 3 weight percent of the polymer composition. The stabilisers may be selected from benzophenones, hindered amine light stabilizers (HALS), triazines, metal complexed organic molecular deactivators and mixtures thereof.

Further the additives may include incorporating stabilisers and retardants to allow for stable storage for up to 12 months prior to application.

The invention also extends to a high voltage electrical insulator used indoors or outdoors up to 1000 kV in AC and DC applications with a fibrous reinforced polymer concrete core.

An insulator core may be made from polymer concrete which includes fibrous reinforcement at a loading of 0.1 to 5 weight percent of the polymeric resin weight and preferably 2.5 to 3 weight percent.

An insulator core may be made from polymer concrete which includes fibrous reinforcement with fibres with a length 1.5 mm to 12 mm and preferably 3 mm to 7 mm.

An insulator core may be made from polymer concrete where the fibrous reinforcement may be inorganic for example glass or ceramic or organic polymeric fibres for example acrylic, polyester, polyamide, polypropylene or polyphenylene-sulphide and where the fibres may or may not be surface treated using silanes or other means of activation such as oxidation with chemical treatments or corona discharge.

An insulator core may be made from polymer concrete where the fibrous reinforcement is homopolymer polyacrylonitrile fibres, 6 mm in length and 0.5 dtex to 8 dtex and preferably 1.5 dtex to 2.5 dtex.

An insulator core may be made from polymer concrete where the fibre is first well dispersed in the resins before the fillers are added to the resin whilst mixing.

An insulator core may be made from polymer concrete where the particulate fillers may include one or a combination of the following; stone, quarts sand, silica flour, crushed glass, ground silicone rubber, glass beads, aluminasilicates including fly ash and other minerals. The fillers may be treated with silanes or titinates or used untreated.

An insulator core may be made from polymer concrete where the fly ash which may be unwashed or washed and graded and where the median particle size of the round particles is 10 to 20 μm and is derived from a pulverised coal boiler on a power station.

An insulator core may be made from polymer concrete where the aluminosilicate round particulate fillers are included at a loading of 20 to 80 percent by weight of the final polymer concrete weight and preferably at a loading of 40 to 60 weight percent.

Further a method for making the polymer concrete core formulation includes the step of combining an organic binder resin with the fillers.

The method for making the polymer concrete core may include the organic binder resin being selected from monomers, oligomers or prepolymerised unsaturated polyesters, including isophthalic and ortopthalic grades and cyclic butyl terephthalate, also vinylesters, methacrylates, acrylates, epoxy compounds, imides, amides, polyphenylenesulphide, polyurethanes and mixtures of any two or more thereof.

In a method of making the polymer concrete core all the particulate fillers to be used may first be homogenously mixed together.

In the production of the polymer concrete formulation for a method of making the polymer concrete core, the fillers may first be wetted with a low molecular weight diluent.

In a method of making the polymer concrete core, the fillers are first mixed and then wetted with styrene before being added stepwise to the mixture of polyester resin, catalyst, accelerator and fibre.

Further a method of making the polymer concrete core includes a situation where the organic binder formulation may also contain the required crosslinking agents, catalysts (low temperature peroxides or the like) inhibitors, retardants, accelerators and emulsifiers/stabilizers which will be known to persons knowledgeable in the field of polymer processing.

A method of making the polymer concrete core includes steps wherein the polymer concrete formulation is degassed by blending for about 20 minutes under reduced pressure to produce a largely void free material and then moulded in an injection-mould, by automatic pressure gelation in a heated metal mould or by hand casting in a supported silicone rubber mould. The cast object may then be post-cured in an oven.

A method of making the polymer concrete core as above where the filler content is between 60 and 94 weight percent of the core and preferably between 75 and 90 weight percent.

Further in the method of making the polymer concrete core as described above the mixed resin and filler formulation may be placed in a mould and the complete mould vibrated and degassed.

Further in the method of making the polymer concrete core the mould may be made from silicone rubber, polyethylene, polypropylene or polyester or any other polymeric mould making material, where the polyolefin or polyester mould is stretch blow moulded.

Further according to the invention a high voltage electrical insulator used indoors or outdoors up to 1000 kV in AC and DC applications has a fibre reinforced polymer core and coated with a hydrocarbon-siloxane containing coating.

The invention also covers a method of making the polymer concrete core where the mould for the polymer concrete core is made from a polymer and no mould release agent is applied.

Further a polymer concrete insulator core produced by the method may be used uncoated as a high voltage insulator.

Further in a method of making the polymer core, the entire polymer core may be coated after demoulding.

Further in a method of making the polymer concrete core, the core may be coated when the core material is in the gel state or before or after the core material has been post cured.

Further in a method of making the polymer concrete core, the coating material may be a polymeric silicone containing material including room temperature vulcanised silicone rubber and siloxane-hydrocarbon based coating formulations.

Further in a method of making the polymer concrete core, the coating may be applied to the inside of the mould before the polymer concrete is introduced to the mould.

Further in a method of making the polymer concrete core, the coating may be applied to the inside of the mould before the polymer concrete is introduced to the mould and the coating formulation is first partially or fully cured before the polymer concrete mix is introduced to the mould.

Further in a method of making the polymer concrete core, the mould, or part of the mould may first be treated with a mould release agent. The mould release agent may be silicone based or polyvinyl alcohol or other standard mould release agent.

Further in a method of making a coated insulator, metal oxide nanoparticles may be placed on the surface after the coating has cured using laser vapour deposition, thermal ablation or a similar technique and then vapour coated by a silane.

### BRIEF DESCRIPTION OF THE DRAWINGS

The invention is now described, by way of a non-limiting example, with reference to the accompanying drawings wherein;

FIG. 1 shows a cross section of a 33 kV 10 kN line post polymer concrete profiled core, (A), with an F-neck profile, (B), thin sheds, (C) at a 15° angle, (D), where all interfaces between the sheds and the central shaft are curved, (E), and moulded onto a metal insert, (F).

FIG. 2 gives a comparison of the shed profile or the polymer concrete insulator core invention, (G) and a typical 33 kV porcelain insulator (H), which both have 7 sheds spaced 32 mm apart. The invention has thinner sheds and a more slender centre shaft. The invention has a flexural strength of typically 32 kN. The invention has high strength due to 3% fibre reinforcement. The low viscosity of the mix which allows moulding in thin sections is due to the incorporation of a high proportion of round filler particles.

FIG. 3 shows an Atomic Force Microscope scan of the coating detailed in example 1 of the preferred embodiment of this invention.

FIG. 4 gives a light microscope image showing that a 1 microliter droplet, with a diameter of 720 microns is about 40 times larger than the spacing between the micron sized humps on the nano and micron roughness hydrophobic surface.

FIG. 5 presents a schematic of a water droplet with a high contact angle at the surface of the low energy surface of a siloxane enriched surface. The methyl groups are directed to the open surface, as the lowest energy conformation of the siloxane chain. The free volume of the siloxane is reduced due to the fact that the siloxane is copolymerised with a hydrocarbon.

FIG. 6 shows a schematic of the surface of the coating with the siloxane moiety phase-separated on the free surface of the hydrocarbon moiety. The amine organofunctional siloxanes are reacted with epoxide groups in the bulk of the resin coating formulation given in the preferred embodiment of this invention.

FIG. 7 gives a schematic depicting a single section of an amino organofunctional siloxane grafted onto the metal oxide silica filler particles such as through the free hydroxyl groups on the surface of the silicon dioxide nanosized and micron sized particles.

FIG. 8 presents a schematic of the phase separated siloxane surface covering in the cured coating when the siloxane-hydrocarbon copolymer or cooligomer is grafted onto the metal oxide micron and nanoparticles and copolymerised with the hydrocarbon resin through hydrolytically stable Si—C bonds.

FIG. 9 shows a typical SEM micrograph showing the phase separated siloxane surface providing roughness on the nano and micron scale in a coating which contains no grafted fillers but 20% w/w organofunctional siloxane oligomers of various molecular weight in an 80% w/w epoxy matrix.

FIG. 10 provides a typical SEM micrograph showing the siloxane treated grafted nano and micron sized fillers pulled to the surface of the coating and covered by a layer of siloxane oligomers and polymers. The surface is rough on the nano and microscale as required for superhydrophobicity as there many air gaps such that water will not easily adhere to and wet the surface. Similar structures are seen on the surfaces of the leaves of many plant species, such as the lotus plant—Biomimetics.

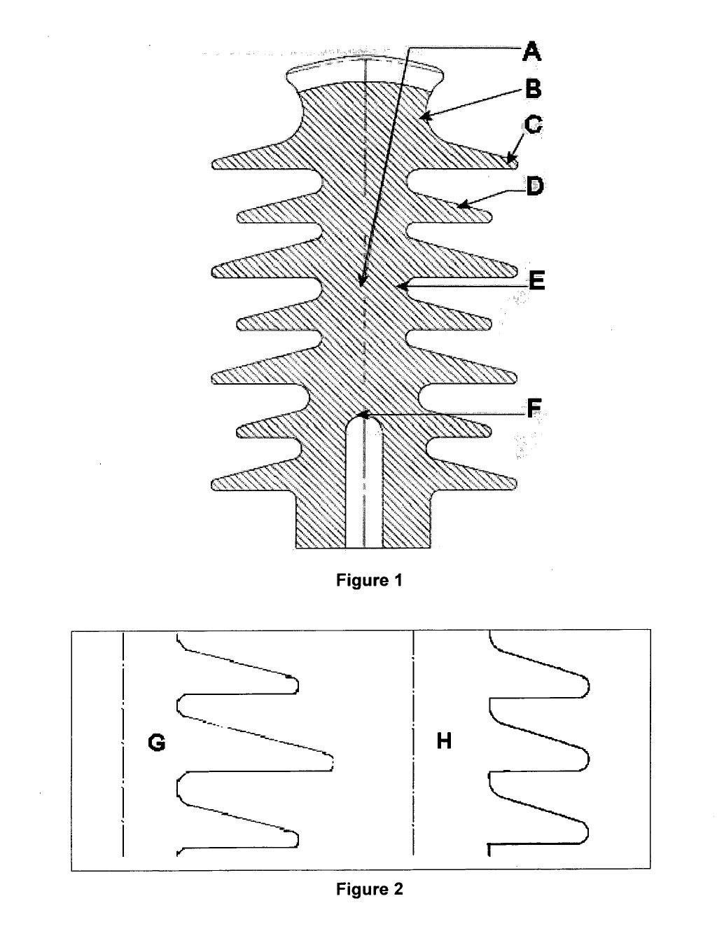

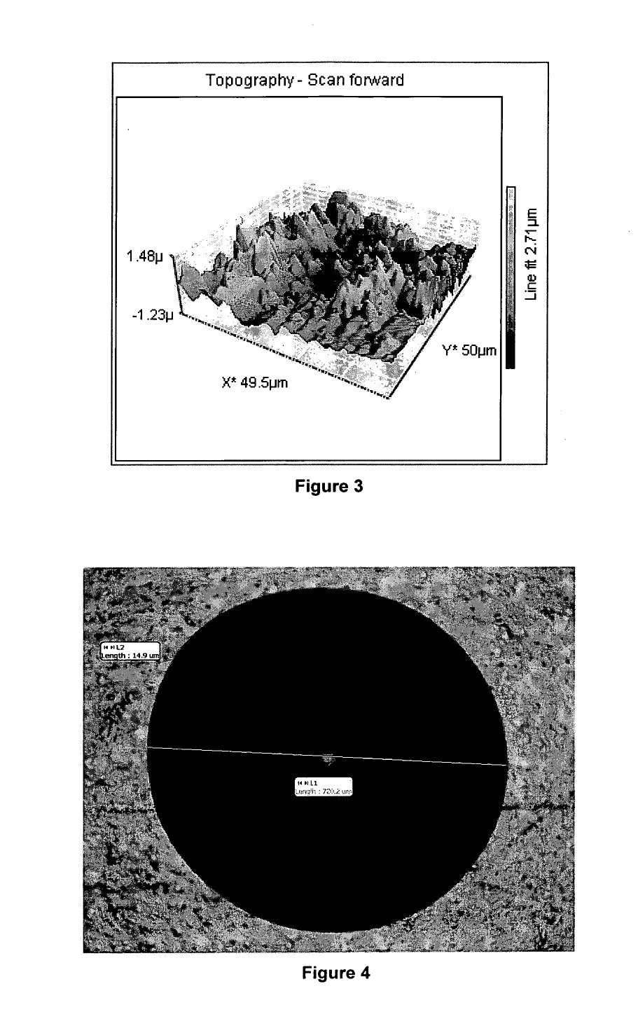

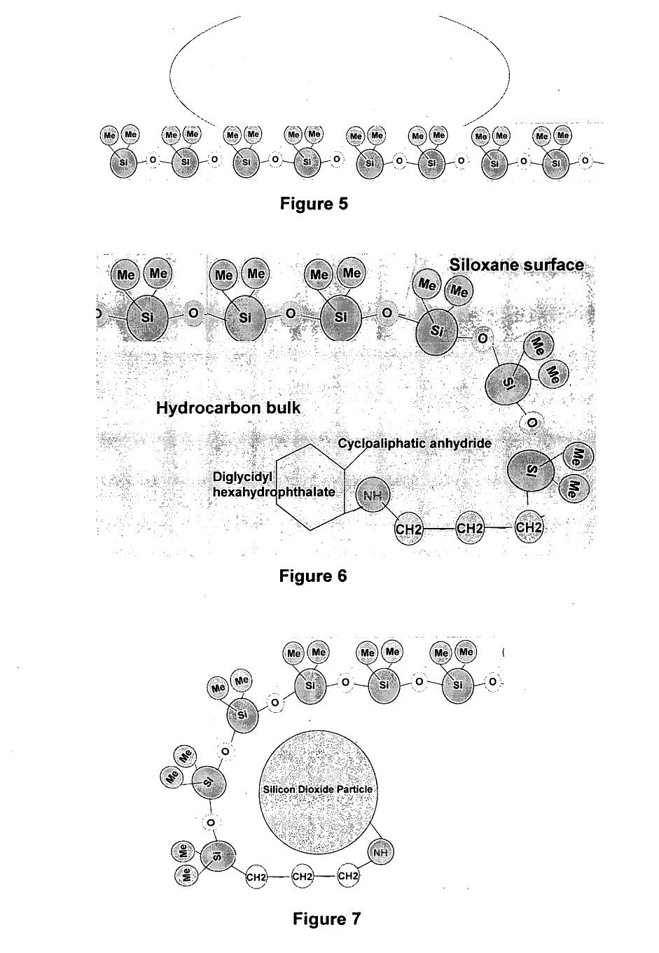

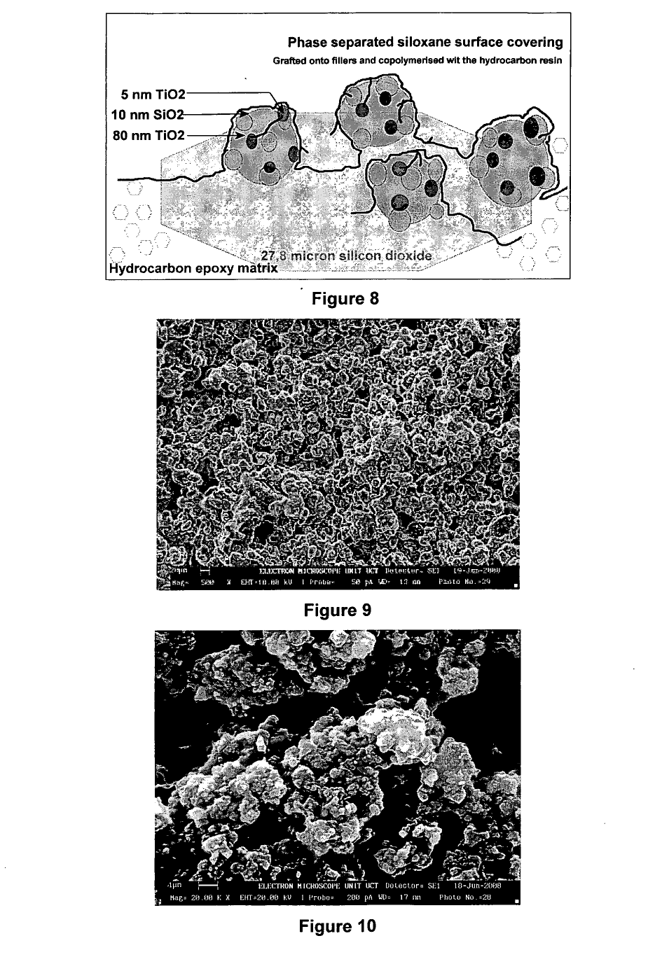

### DETAILED DESCRIPTION AND BEST METHOD OF CARRYING OUT THE INVENTION

The coating composition of the present invention provides a phase separated siloxane-hydrocarbon copolymer surface layer which is hard and hydrophobic and can be made permanently superhydrophobic by the addition of nano-particles. The siloxane oligomer/polymer precursor is terminated with chemically reactive group(s). The bond between the siloxane moiety and the hydrocarbon functional moiety is a silicon atom directly bonded to a carbon atom. The phase separation of the siloxane moiety onto the open free surface is a time-dependant process and must be allowed to occur prior to the final cure of the coating composition.

In the method of the invention, the siloxane moiety phase separates from the hydrocarbon bulk and forms a nanometer to micron meter thick layer at the free surface, which is chemically bound into the bulk hydrocarbon material, and therefore the siloxane cannot migrate. In addition the free volume of the siloxane moiety is reduced thereby limiting the ability for rotational vibrations on the Si—O ether bonds of the backbone (flipping of the methyl groups). Furthermore this siloxane-hydrocarbon inhibits the degradation of the siloxane by preventing the “back-biting” initiation step of the degradation mechanism which may be catalysed by the remnant platinum catalyst residues in conventional silicone rubber formulations.

The siloxane-hydrocarbon phase-separated coating produces a hard, hydrophobic surface, with a surface tension of less than 35 dynes·cm⁻¹. The surface is self-cleaning in wet and high humidity conditions thereby limiting the build-up of conductive pollutants on the insulators surface and minimising the surface leakage current. The mechanical and electrical requirements for high voltage NCI are covered in IEC 61109.

The invention thus provides a siloxane-hydrocarbon copolymer layer with metal oxide nano-particles at the surface which provides a permanently hydrophobic and hard surface when applied to a fibre reinforced polymer concrete core for application as a high voltage insulator.

It is an advantage of the invention illustrated that the invention provides both indoor and outdoor high voltage insulators from 1 kV to 1000 kV, AC or DC with a creepage length of 10 mm·kV⁻¹ to 50 mm·kV⁻¹ which can be used in compression mode as line-post insulators or in suspension mode in the form of long-rod insulators. The nano-composite modified polymer concrete insulator has a UV stabilized coating filled with nanoparticles and a nano-phase separated copolymer providing a hard yet hydrophobic surface. The invention uses inexpensive resins as the binder and 20% more low cost fillers since the polymer concrete core is totally enclosed and protected by the hard nano-composite coating. It is a further advantage that the fibrous reinforcement results in reduced weight in each flexural strength class. The composition of the invention produces a nanometer thick, phase-separated, siloxane copolymer coating chemically bonded on the surface.

The products produced by the method of the invention are also less expensive than similar products made from other materials.

It is a further advantage of the invention is that the products produced by the method of the invention have superior performance due to their permanent hydrophobicity. The hydrophobic insulator surface suppresses leakage currents, thereby limiting surface heating, tracking and corona induced material damage thereby resulting in an extended service life.

Insulators are sometimes commercially coated with RTV silicones when used in high pollution regions. However, pure RTV silicones have a high water absorption coefficient and this leads to interfacial problems, resulting in the peeling of coatings. The reactive silicone hydrocarbon copolymer coating of the invention has a higher density and lower water absorption than prior art coatings.

It is a further advantage of the invention that the coating produces a self-cleaning surface. The surface has a high hardness value due to the incorporation of nanoparticulate fillers, unlike silicone, EVA and EPDM elastomers. Hard surfaces will collect less conductive pollutants and will clean easily due to the low adherence on the hard surface.

The coating of the invention also has superior UV resistance when compared with prior art coatings. Due to the low volume of the coating material relative to the bulk, it is cost effective to add UV stabilizers to the formulation. Since the siloxane units are end capped with hydrocarbons they cannot degrade by the “back-biting” mechanism from the chain ends where the degradation is typically initiated in HTV and RTV silicone rubber based materials. In addition a different catalyst will be employed as the curing agent. The platinum based catalyst used in most silicone rubber formulations for NCI have been proven to also catalyse the degradation process. The UV stability is accomplished by the addition of light stabilisers in only the coating formulation. The nanoparticulate filler particles of Al(OH)₃, SiO₂ and TiO₂ (anatase form) also have good UV resistance.

The invention allows the production of new, light-weight, slender design-profiles with high flexural/impact strength. The addition of fibrous and high aspect ratio fillers radically improves the impact resistance of the modified polymer concrete insulators of the invention. The addition of round filler particles in the form of washed and graded fly ash reduces the viscosity of the highly filled polymer concrete formulation allowing the moulding of convoluted profiles. For an insulator made from such a polymer concrete, the sheds can be made thinner than those using a conventional polymer concrete or porcelain. For example using the formulation given in example 1 of the preferred embodiment one can produce a 33 kV line post polymer concrete insulator with an F-neck and 7 alternating sheds, 32 mm apart and 6 mm at the edge and all curved surfaces, where the arcing distance is 297.3 mm and leakage distance 1051.97 mm i.e. 31 mm/kV for 33 kV and 47.8 mm/kV for 22 kV. The weight of the insulator product is 4.4 kg versus 7.1 kg for a porcelain insulator with a similar rating. The flexural strength is about 32 kN. Such an insulator is depicted in FIG. 1.

Prior art line post cycloaliphatic insulators are often easily damaged during transportation and need to be packed in individual wooden crates. Insulators with hairline cracks may explode when energized. The coating of the invention provides a tough, scratch resistant surface. Line post insulators from ceramics and cycloaliphatic are bulky and heavy. The use of fibres increases the tensile and flexural strength of the insulators allowing for a slimmer core profile and subsequent lower weight for a given flexural class. This results in reduced transportation costs and will make line design and the physical line construction easier.

It is a further advantage of the invention that the insulators of the invention have an extended service life especially in polluted areas due to erosion resistance. The high erosion resistance improves performance especially in sandy, desert and polluted coastal environments due to the “super-hard” surface produced by the coating composition of the invention. Lower leakage currents also occur due to the low dust deposit density on the hard surface and less damage by tracking and corona.

### Preferred Embodiment

### Example 1 of the Polymer Concrete Core

The formulation set out below gives the weight of each component for 4.436 kg of the final polymer concrete formulation.

The particulate dry fillers are first weighed and thoroughly mixed in a catering industry blade mixer. The fillers were 200 g SiO₂ with a mean particle size of 27.8 micron, S15 supplied by Idwala Minerals, 1000 g SiO₂, with a mean particle size of 275 μm, AFS55 supplied by Consul Minerals, and 2000 g fly ash, DuraPozz supplied by Ash Resources with a mean particle size of 15 μm. The fillers were wetted with 400 g styrene, NCS monomer and mixed well.

The polymer concrete formulation is prepared from 18 weight percent (0.800 kg) isopthalic unsaturated polyester resin (density=1.11 to 1.12) and MW 3000 to 3500, NCS992 supplied by NCS resins. Approximately 0.004 kg (0.5% of the resin weight) accelerator, cobalt napthenate in a diluent, AC1 supplied by NCS Resins was added to the resin and stirred. The catalyst, which was added at 1% of the resin weight, (0.008 kg) was 50% methylethylketone peroxide, 1338-23-4, (MEKP) in 50% phlegmatiser such as a phthalate, (Curox M-200 supplied by Degussa). And stirred before adding 24 g (3% of the resin weight) homopolymer polyacrylonitrile fibres, 2.5 dtex and 6 mm in length, Ricem supplied by Montefibre SpA. The resin was placed in a mixer and blended for 2 minutes. Thereafter the wetted fillers were added in small batches and then the polymer concrete was mixed for 2 minutes.

The polymer concrete composition is vibrated for 5 minutes to remove bubbles. The viscosity was in the range of 9000 to 10000 centi-Poise. The convoluted core was moulded in a silicone rubber mold containing a mounted mild steel screw insert. The mold, in a metal support frame was vibrated and vacuumed during the filing process. The moulded product was post cured at 80° C. for 3 hours.

### Example 1 of the Coating Composition

This example of the coating can be generically described as follows. A highly epoxide enriched cycloaliphatic epoxy resin reacted with and blended with medium molecular weight amine functional siloxane, containing sonicated nanosized siloxane grafted, SiO₂ (4 nm, 10 nm, and 15 μm) and TiO₂ (5 nm and 80 nm) fillers and rheology modified with nanosized TiO₂ and Al₂(OH)₃ and micronsized SiO₂, brush coated from a toluene solution. Cured at 120° C. in 15 minutes. Post cured at 80° C. for 10 hours.

The grafted fillers are first prepared. About 3 g 7 nm 390 m²·g⁻¹±40 m²·g⁻¹ silicon dioxide [112945-52-5] SiO₂ is reacted with 2 ml 3-aminopropyl terminated polydimethylsiloxane, [97917-34-5] Amine density 1.5 to 2.2 [mmol·g⁻¹] in which the siloxane moiety contained about 15 {—Si(CH₃)₂—O—} linkages, in 50 g of toluene and left to stir at 50° C. on a magnetic stirrer hotplate for 72 hours in order to graft the oligomer chains onto the surface of the silica particles.

About 4 g 10 nm silicon dioxide 300 m²·g⁻¹±30 m²·g^{-1 [}112945-52-5] SiO₂ silanol group density SiOH/nm² of 1 is reacted with 2 ml 3-aminopropyl terminated polydimethylsiloxane, [97917-34-5] Amine density 0.17-0.22 [mmol·g⁻¹] in which the siloxane moiety contained about 140 {—Si(CH₃)₂—O—} linkages, in 20 g of toluene and left to stir at 50° C. on a magnetic stirrer hotplate for 72 hours in order to graft the oligomer chains onto the surface of the silica particles.

About 10 g 27.8 micron milled quartzite silicon dioxide SiO₂ is reacted with 5 ml poly(octadecyl methacrylate-co-methyl methacylate) in 20 g of toluene and left to stir at 50° C. on a magnetic stirrer hotplate for 72 hours in order to graft the oligomer chains onto the surface of the silica particles.

About 20 g 27.8 μm milled quartzite silicon dioxide SiO₂ is reacted with 2 ml 3-aminopropyl terminated polydimethylsiloxane, [97917-34-5] amine density 1.5 to 2.2 [mmol·g⁻¹] in which the siloxane moiety contained about 15 {—Si(CH₃)₂—O—} linkages, and 1 ml alkyl ester silicone wax in 20 g of toluene and left to stir at 50° C. on a magnetic stirrer hotplate for 72 hours in order to graft the oligomer chains onto the surface of the silica particles.

About 0.2 g 5 nm titanium dioxide, TiO₂ is reacted with 2 ml 3-aminopropyl terminated polydimethylsiloxane, [97917-34-5] amine density 1.5 to 2.2 [mmol·g⁻¹] in which the siloxane moiety contained about 15 {—Si(CH₃)₂—O—} linkages, and 2 ml 3-aminopropyl terminated polydimethylsiloxane, 97917-34-5 amine density 0.17-0.22 [mmol·g⁻¹] in which the siloxane moiety contained about 140 {—Si(CH₃)₂—O—} linkages in 20 g of toluene and left to stir at 50° C. on a magnetic stirrer hotplate for 72 hours in order to graft the oligomer chains onto the surface of the titanium oxide particles. The solution was sonicated for 30 minutes at the start and every 24 hours.

About 10 g 80 nm titanium dioxide, TiO₂ is reacted with 2 ml alkyl ester silicone wax 10 g of toluene and left to stir at 50° C. on a magnetic stirrer hotplate for 72 hours in order to graft the oligomer chains onto the surface of the titanium oxide particles. The solution was sonicated for 30 minutes at the start and every 24 hours.

About 10 g 80 nm titanium dioxide, TiO₂ is reacted with 3-aminopropyl terminated polydimethylsiloxane, [97917-34-5] amine density 0.17-0.22 [mmol·g⁻¹] in which the siloxane moiety contained about 140 {—Si(CH₃)₂—O—} linkages and 1 ml alkyl ester silicone wax 10 g of toluene and left to stir at 50° C. on a magnetic stirrer hotplate for 72 hours in order to graft the oligomer chains onto the surface of the titanium oxide particles. The solution was sonicated for 30 minutes at the start and every 24 hours.

The resin is prepared in a separate container. About 40 g of a proprietary mix ratio of hexahydrophthalic acid diglycidyl ester, [5493-45-8], MW 284.34 epoxy equiv·kg⁻¹ 5.80 to 6.10 and 3-,4-Epoxycyclohexylmethyl-3,4-Epoxycyclohexanecarboxylate, [2386-87-0], EEW=131 to 135, MW 252 is with 15.52 g 3-aminopropyl terminated polydimethylsiloxane amine density 0.62-0.74 [mmol/g] in which the siloxane moiety contained about 36 {—Si(CH₃)₂—O—} linkages, in a container with 40 g toluene whilst stirring at room temperature. After 10 minutes about 18.88 g methyl hexahydrophthalic anhydride [25550-51-0] 10 g of the co-reactive curing agent, Bis(2-aminoethyl)amine, tertiary amine [111-40-0], is added to the stirring solution.

The treated grafted fillers are then added to the resin solution and UV stabilisers added. About 1.87 g (1.77% of the polymer weight) of 2-[4-[(2-Hydroxy-3-dodecyloxypropyl)oxy]-2-hydroxyphenyl]-4,6-bis(2,4-dimethylphenyl)-1,3,5-triazine 153519-44-9] and 2-[4-[(2-Hydroxy-3-tridecyloxypropyl)oxy]-2-hydroxyphenyl]-4,6-bis(2,4-dimethylphenyl)-1,3,5-triazine [107-98-2], 85% in 1 methoxy-2-propanol, together with 2 g ground Hydroxyphenyltriazine powder.

Dried fillers are added to alter the viscosity to provide a coating materials which is applied by brushing. The dried fillers are first ground with a mortar and pestle. The added fillers are about 10 g 2.2 μm aluminium trihydrate, 20 g, 27.8 μm silicon dioxide and 20 g, 80 nm titanium dioxide. The mixture of the resin, the treated fillers and untreated fillers are then sonicated for 30 minutes and applied immediately or stored in a freezer.

The polymer concrete insulator is attached to a drill press using the metal insert and rotated at 60 rpm. The coating is applied using a squirrel-hair brush. The coating is cured in an air-circulating oven at 120° C. for 15 minutes. After the coated insulator core has cooled it is then post-cured at 80° C. for 3 hours.

The approximate mol ratio of the resin components is approximately epoxy/anhydride/amine/siloxane=0.1407:0.1123:0.0055:0.0194=1:0.7982:0.0391:0.1379. The mass ratio of the resin to treated filler to untreated filler is 80.94:57.2:50 or 1:0.7067:0.6177 or as a percentage 43.0:30.4:76.6.

So total formulation of Example 1 contains 76.4 g resin with 15.52 g aminofunctional siloxane+57.2 g treated fillers+50 g dry fillers+13.58 g other organofunctional siloxanes+3.87 g stabilisers in 180 g toluene, and 5 ml alkyl acrylate. The total polymer content is 105.5 g polymer. The ratio of the hydrocarbon resin to the total filler is 76.4 g:107.2 g=1:1.403=71.3:28.7. The ratio of the Mass hydrocarbon:mass siloxane=81.4:29.1=1:0.357=73.7:26.3

| | |
|---|---|
| Volume and surface resistivity | ASTM D-257,92 |
| Arc resistance | ASTM D-495,89 |
| Comparative Tracking Index | IEC-112,79 |
| Dielectric Strength | ASTM D-149,92 |
| Flexural Strength | ASTM D 790,92 |

### Example 1 of a Moulded Insulator Object

A 33 kV 10 kN class insulator with an F-neck for outdoor use on an AC distribution network with a creepage distance of 1051.97 mm and creepage length of 31 mm/kV was manufactured in accordance with the method of the invention. The total weight is 4.4 kg versus 7.1 kg for a porcelain insulator with a similar rating.

### INDUSTRIAL APPLICATION

The invention has industrial application for use in distribution and transmission of electricity.

1. A coated product, comprising:
an object; and
a coating applied to the object, wherein the coating includes a siloxane hydrocarbon copolymer including a siloxane moiety corresponding to an organofunctional siloxane oligomer or polymer and a hydrocarbon moiety corresponding to a hydrocarbon based oligomer or polymer, the coating further includes particle fillers and other additives, wherein, within the siloxane moiety, a silicon atom is directly covalently bonded to a carbon atom of the hydrocarbon moiety.

2. (canceled)

3. The coated product of claim 1 wherein, once the coating is cured, the siloxane hydrocarbon copolymer is phase separated such that a surface region of the coating is enriched in the siloxane moiety relative to a bulk of the coating, and the siloxane moiety is covalently bonded to the hydrocarbon moiety in the bulk.

4. The coated product of claim 1 wherein the particle fillers include nanosized filler particles, and the nanosized filler particles are enriched in the surface region relative to the bulk of the coating and provide ordered micron and nanoscaled roughness to the surface region to create a hard, self-cleaning, and superhydrophobic surface and photocatalytic degradation of organic substances.

5. The coated product of claim 1 wherein the organofunctional siloxane oligomer or polymer corresponds to an organofunctional polydimethylsiloxane selected from oligomers or polymers of the formula (A′) or (A″) 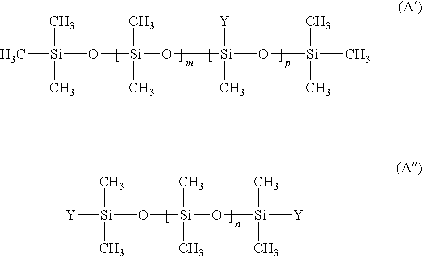
and including from 5 to 2000 siloxane groups {—Si(CH₃)₂—O—}, in which Y is a reactive substituent.

6. The coated product of claim 5 in which the organofunctional polydimethylsiloxane is selected from the following: 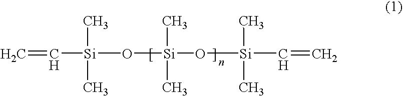
(1) vinyl terminated polydimethylsiloxanes, CAS: [68083-19-2]; n=5 to 480; 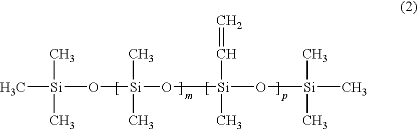
(2) trimethylsiloxy terminated, vinylmethylsiloxane-dimethylsiloxane copolymers, CAS: [67762-94-1]; m=10 to 100; p=1 to 5; 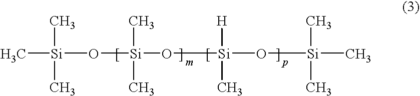
(3) trimethylsiloxy terminated, methylhydrosiloxane-dimethylsiloxane copolymers, CAS: [68037-59-2]; 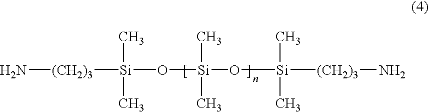
(4) α,ψ-Aminopropyl terminated polydimethylsiloxane, CAS: [106214-84-0]; n=10 to 2000; 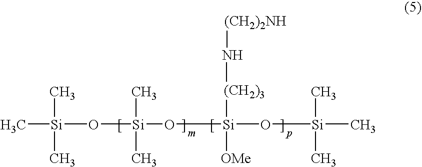
(5) α,ψ-Aminopropyl terminated polydimethylsiloxane, CAS: [106214-84-0]; 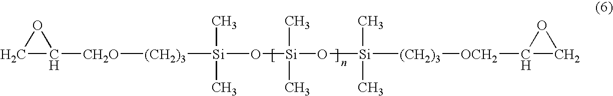
(6) epoxypropoxypropyl terminated polydimethylsiloxanes, CAS: [102782-97-8]; 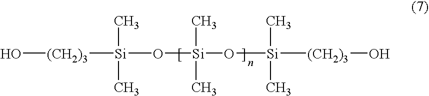
(7) carbinol (hydroxyl) terminated polydimethylsiloxanes, CAS: [156327-07-0]; 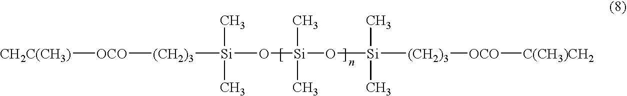
(8) methacryloxypropyl terminated polydimethylsiloxanes, CAS: [58130-03-3]; and 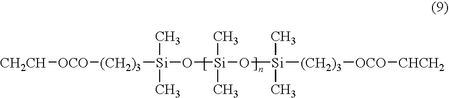
(9) (3-Acryloxy-2-hydroxypropyl) terminated polydimethylsiloxanes, CAS: [128754-61-0].

7. The coated product of claim 5 where the organofunctional polydimethylsiloxane (A′) or (A″) has an associated molecular weight from 116 to about 35000 g·mol⁻¹ and the reactive substituent Y includes a reactive end group which is separated from the siloxane groups by 2 to 10 methylene groups.

8-9. (canceled)

10. A method of preparing a coating, comprising:
grafting the organofunctional polydimethylsiloxane (A′) or (A″) of claim 5 onto metal oxide filler particles (MO) in a dilute solution of the filler particles in a solvent whilst stirring,
preparing a resin (C),
adding the grafted filler particles to the resin (C) to form (A′)ₓ(MO)(A′)ₓ or (A″)ₓ(MO), and
adding other fillers and additives.

11. (canceled)

12. The method of claim 10 wherein the filler particles include at least one of: (a) is anatase or rutile titanium dioxide particles, (b) silicon oxide particles, (c) aluminium oxide particles, and (d) zinc oxide particles, the filler particles include at least one of (a) nanosized particles, having sizes from 2 to 100 nm, and (b) micron sized particles, and the filler particles are grafted separately or together after sonication onto a single organofunctional polydimethylsiloxane or a mixture of different organofunctional polydimethylsiloxanes in an organic solvent.

13-14. (canceled)

15. A method of preparing a coating, comprising:
preparing a resin (C),
adding the organofunctional polydimethylsiloxane (A′) or (A″) of claim 5 to the resin (C) to produce a formulation, and
adding fillers and other additives to the formulation.

16. The method of any of claims 10 and 15 wherein preparing the coating includes one of the following:
(a) the organofunctional polydimethylsiloxane (A′) or (A″) is separately copolymerised with a functional oligomer or monomers (B) using a free-radical, thermal or UV curing system to produce a copolymer of the type (A′)(B)(A′) or (A″)(B), and the copolymer (A′)(B)(A′) or (A″)(B) is blended with the resin (C) to form a resin composition (D1) as an interpenetrating network in a solvent;
(b) the organofunctional polydimethylsiloxane (A′) or (A″) is separately copolymerised with a functional oligomer or monomers (B) using a free-radical, thermal or UV curing system to produce a copolymer of the type (A′)(B)(A′) or (A″)(B), and the copolymer (A′)(B)(A′) or (A″)(B) is reacted with the resin (C) to form a copolymer by a free-radical, thermal, IR or UV curing system in a common solvent to form a resin composition (D2);
(c) the organofunctional polydimethylsiloxane (A′) or (A″) is directly blended with the resin (C) in a solvent to form a low viscosity resin composition (D3), and the resin composition (D3) is then cured; and
(d) the organofunctional polydimethylsiloxane the fourth route (A′) or (A″) is polymerized directly with the resin (C) in a free-radical, thermal or UV activated cure system to form a resin composition (D4).

17. (canceled)

18. The method of claim 16 wherein the functional oligomer or monomers (B) and the resin (C) are independently selected from polymethylmethacrylates, polymethacrylates, polyacrylates, cycloaliphatic or other epoxy compounds, polyamides, polyesters, PET or PBT including cyclic butylterepthalate, vinyl esters, polyimides, polyphenylene-sulphide, polysiloxanes, polyolefins; polyurethanes, and copolymers thereof, and wherein polymerization is initiated by ultraviolet radiation, infrared radiation, or the addition of a free radical initiator, and wherein the additives include at least one of: (a) an organic dye, (b) an inorganic pigment; (c) a low molecular weight siloxane; (d) a flame retardant; and (e) solid glass spheres having sizes from 100 nm to 1000 micron and from 0 and 15 weight percent of the formulation to adjust a surface hardness.

19-23. (canceled)

24. A method of preparing a coating, comprising:
preparing a resin (C),
adding the organofunctional polydimethylsiloxane (A′) or (A″) of claim 5 to the resin (C) to produce a formulation, and
adding fillers to the formulation, wherein adding the fillers includes at least one of the following:
incorporating the fillers as discrete particles; and or
applying the fillers to a surface of the coating using laser vapor deposition;
forming the fillers in situ by a sol-gel technique;
incorporating the filler in the formulation; and
dip-coating from a solution of titanium, zirconium, aluminium or silicon precursors.

25-30. (canceled)

31. A high voltage electrical insulator, comprising:
a fibrous reinforced polymer concrete core; and
a siloxane hydrocarbon copolymer incorporated in or applied to the polymer concrete core, the siloxane hydrocarbon copolymer including a siloxane moiety corresponding to an organofunctional siloxane oligomer or polymer and a hydrocarbon moiety corresponding to a hydrocarbon based oligomer or polymer, wherein, within the siloxane moiety, a silicon atom is directly covalently bonded to a carbon atom of the hydrocarbon moiety.

32. The high voltage electrical insulator of claim 31 wherein the polymer concrete core includes fibrous reinforcement at a loading of 0.1 to 5 weight percent of a polymeric resin weight, with fibers having lengths from 1.5 mm to 12 mm, the fibers include at least one of (a) inorganic fibers and (b) polymeric fibers, and the fibers are optionally surface treated or activated.

33-34. (canceled)

35. The high voltage electrical insulator of claim 31 wherein the polymer concrete core includes polyacrylonitrile fibers of 0.5 dtex to 8 dtex.

36. The high voltage electrical insulator of claim 31 wherein the polymer concrete core is a highly filled core, and fibers are first well dispersed in a resin before fillers are added to the resin whilst mixing.

37. The high voltage electrical insulator of claim 31 wherein the polymer concrete core includes particulate fillers selected from at least one of stone, quarts sand, silica flour, crushed glass, ground silicone rubber, glass beads, and aluminasilicates.

38. The high voltage electrical insulator of claim 31 wherein the polymer concrete core includes fly ash, and a median particle size of the fly ash is from 10 to 20 μm, and the fly ash is derived from a pulverised coal boiler on a power station.

39-48. (canceled)

49. A method of making a high voltage electrical insulator, comprising:
preparing a fibrous reinforced polymer concrete core using a polymeric mold; and
applying a coating to the polymer concrete core, wherein the coating includes a siloxane hydrocarbon copolymer including a siloxane moiety corresponding to an organofunctional siloxane oligomer or polymer and a hydrocarbon moiety corresponding to a hydrocarbon based oligomer or polymer, the coating further includes particle fillers and other additives, wherein, within the siloxane moiety, a silicon atom is directly covalently bonded to a carbon atom of the hydrocarbon moiety.

50-52. (canceled)

53. The method of claim 49 wherein the polymer concrete core is coated after demolding or the coating is applied to an inside of the polymeric mold before a polymer concrete is introduced into the polymeric mold.

54-59. (canceled)
